(19) United States
(12) Patent Application Publication
(10) Pub. No.: US 2026/0156854 A1
(43) Pub. Date: Jun. 4, 2026

(54) METHOD FOR FORMING FLASH MEMORY

(71) Applicant: Winbond Electronics Corp., Taichung City (TW)

(72) Inventors: Ying-Ju CHEN, Taichung City (TW); Cheng-Pu HO, Taichung City (TW); Jeng-Yang LIN, Taichung City (TW); Chih-Jung NI, Taichung City (TW)

(21) Appl. No.: 19/322,188

(22) Filed: Sep. 8, 2025

(30) Foreign Application Priority Data
Dec. 2, 2024 (TW) 113146529

(51) Int. Cl. H10D 30/01; H01L 21/02; H01L 21/311; H10B 41/30; H10D 30/68

(52) U.S. Cl. CPC H10D 30/0411; H10P 14/6309; H10P 14/6339; H10P 14/6682; H10P 14/6687; H10P 14/69215; H10P 50/283; H10B 41/30; H10D 30/6891

(57) ABSTRACT

A method for forming a flash memory is provided. The method includes forming an isolation structure surrounding a plurality of active regions, forming a plurality of first gate electrode layers respectively on the active regions, depositing a first silicon oxide layer along the upper surface and sidewalls of the first gate electrode layers and the upper surface of the isolation structure, performing a first dry etching process to thin down the first silicon oxide layer, performing a first wet etching process to remove the first silicon oxide layer and recess the isolation structure, and forming a second gate electrode layer surrounding the first gate electrode layers.

### CROSS REFERENCE TO RELATED APPLICATIONS

This Application claims priority of Taiwan Patent Application No. 113146529, filed on Dec. 2, 2024, the entirety of which is incorporated by reference herein.

### BACKGROUND OF THE DISCLOSURE

### Field of the Disclosure

The present disclosure relates to a method for forming a flash memory, and in particular, it relates to a method for forming a floating gate electrode layer of a flash memory.

### Description of the Related Art

In order to increase the element density within a flash memory device and improve its overall performance, the technology of manufacturing flash memory devices continues to strive towards miniaturization of element dimensions, which is also an important issue that must be addressed in current process improvement.

### BRIEF SUMMARY OF THE DISCLOSURE

Embodiments of the present disclosure provide a method for forming a flash memory. The method includes forming an isolation structure around a plurality of active regions. The method includes forming a plurality of first gate electrode layers respectively on the active regions; depositing a first silicon oxide layer along upper surfaces and sidewalls of the first gate electrode layers and an upper surface of the isolation structure. The method includes performing a first dry etching process to thin the first silicon oxide layer. The method includes performing a first wet etching process to remove the first silicon oxide layer and recess the isolation structure. The method includes forming a second gate electrode layer around the first gate electrode layers.

Embodiments of the present disclosure provide a method for forming a flash memory. The method includes forming a strip pattern on a semiconductor substrate, wherein the strip pattern includes active regions and a mask layer on the active region. The method also includes forming an isolation structure around the strip pattern, removing the mask layer of the strip pattern, forming a floating gate electrode layer on the active region, and trimming the floating gate electrode layer. The trimming includes oxidizing a first portion of the floating gate electrode layer to form a first silicon oxide layer. The method also includes performing a first wet etching process to remove the first silicon oxide layer and to recess the isolation structure, and forming a control gate electrode layer on the isolation structure and the floating gate electrode layer.

### BRIEF DESCRIPTION OF THE DRAWINGS

The present disclosure can be more fully understood by reading the subsequent detailed description and examples with references made to the accompanying drawings, wherein:

FIGS. 1 to 12 show cross-sectional views of different stages of forming a flash memory according to some embodiments of the present disclosure;

FIG. 13 shows a graph illustrating the relationship between the number of atomic layer deposition cycles and silicon consumption according to some embodiments of the present disclosure.

### DETAILED DESCRIPTION OF THE DISCLOSURE

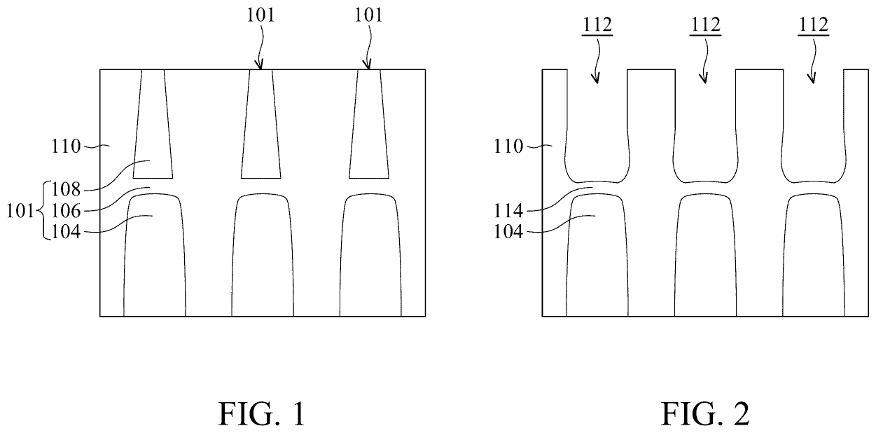

Referring to FIG. 1, a plurality of strip patterns 101 are formed on a semiconductor substrate (not shown). In some embodiments, the semiconductor substrate is an elemental semiconductor substrate, such as a silicon substrate or a germanium substrate, or a compound semiconductor substrate, such as a silicon carbide substrate or a gallium arsenide substrate. In some embodiments, the semiconductor substrate may be a semiconductor-on-insulator (SOI) substrate.

The strip patterns 101 includes active regions 104, a pad oxide layer 106, and a mask layer 108. The formation of the strip patterns 101 includes sequentially forming the pad oxide layer 106 and the mask layer 108 on the semiconductor substrate, followed by patterning the mask layer 108, the pad oxide layer 106, and the semiconductor substrate to form a plurality of trenches, with the strip patterns 101 protruding from between the trenches.

In some embodiments, the pad oxide layer 106 is a silicon oxide layer, which can be formed by thermal oxidation, in-situ steam generation (ISSG), chemical vapor deposition (CVD), or atomic layer deposition (ALD). The mask layer 108 is a silicon nitride layer, which can be formed by chemical vapor deposition or atomic layer deposition. The portion of the semiconductor substrate protruding from between the trenches forms the active regions 104.

An isolation structure 110 is formed to fill the trenches and to surround the strip patterns 101. The isolation structure 110 may include a plurality of silicon oxide layers formed using different deposition techniques. For example, a high aspect ratio process (HARP) may be used to deposit a silicon oxide liner layer along the sidewalls and top surfaces of the strip patterns 101. Spin-on-glass (SOG) is then deposited on the silicon oxide liner layer and beyond the trenches. An annealing process is performed on the spin-on glass. The spin-on glass is planarized by chemical mechanical polishing (CMP). The spin-on glass is recessed by an etching process so as to form trenches again between the strip patterns 101.

Then, a silicon oxide layer is deposited on the spin-on glass using high-density plasma chemical vapor deposition (HDPCVD), overfilling the trenches. The HDPCVD silicon oxide layer is then planarized by chemical mechanical polishing (CMP) until the mask layer 108 is exposed. Although FIG. 1 shows no physical boundary between the isolation structure 110 and the pad oxide layer 106, in other embodiments, a physical boundary may exist between the isolation structure 110 and the pad oxide layer 106.

Referring to FIG. 2, an etching process (e.g., a wet etching process) is used to remove the mask layer 108 of the strip patterns 101 to form trenches 112. Next, an etching process (e.g., a wet etching process) is performed to shrink the isolation structure 110, thereby laterally expanding the trenches 112. Enlarging the trenches 112 can reduce the difficulty of the subsequent deposition process of the floating gate electrode layers, for example, by reducing the risk of voids or seams formation within the floating gate electrode layers, thereby improving the yield and reliability of the semiconductor memory device. Furthermore, the gate coupling ratio between the control gate electrode layer and the floating gate electrode layers can be increased.

Next, a tunnel oxide layer 114 is formed on the upper surface of the active region 104. The formation of the tunnel oxide layer 114 includes recessing the pad oxide layer 106 using a cleaning process (e.g., using a wet etching process), followed by oxidizing the active regions 104 using an in-situ steam generation method to form silicon oxide on the remaining pad oxide layer 106. Thinning the pad oxide layer 106 by the cleaning process and forming silicon oxide by the in-situ vapor generation method can improve the quality of the tunnel oxide layer 114.

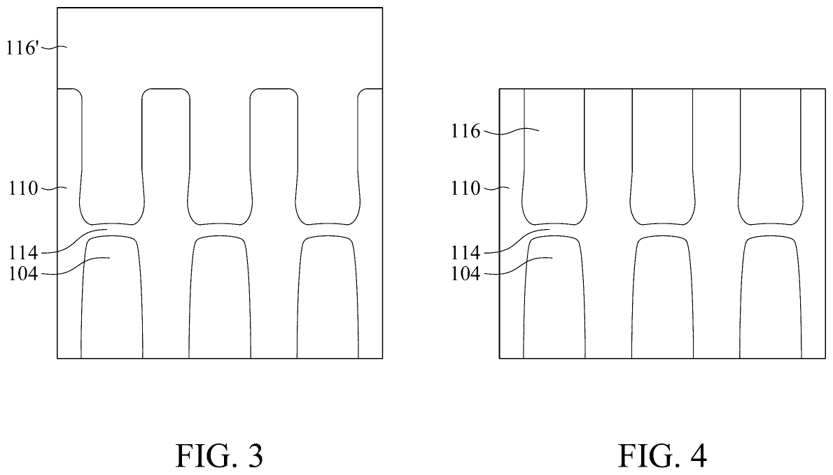

Referring to FIG. 3, an electrode material 116′ is formed on the semiconductor structure of FIG. 2 to overfill the trenches 112 and cover the isolation structure 110. The electrode material 116′ may be polysilicon, amorphous silicon, or a combination thereof. The electrode material 116′ can be deposited using chemical vapor deposition.

Referring to FIG. 4, the electrode material 116′ is planarized by chemical mechanical polishing to expose the upper surface of the isolation structure 110. The remaining electrode material 116′ forms floating gate electrode layers 116 respectively located above the active regions 104.

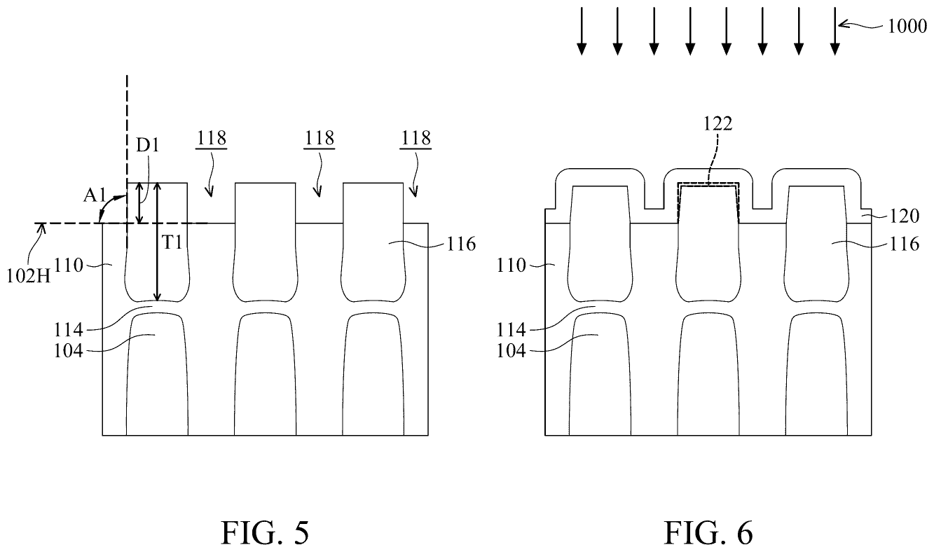

Referring to FIG. 5, an etching process (e.g., a wet etching process) is used to recess the isolation structure 110 to form trenches 118 that partially exposes the sidewalls of the floating gate electrode layers 116. The ratio (D1/T1) of the depth D1 of the trenches 118 to the thickness T1 of the floating gate electrode layers 116 ranges from approximately 1/10 to approximately 7/10. The sidewalls of the floating gate electrode layers 116 intersect a plane 102H parallel to the main surface of the semiconductor substrate 102 on the side outside the floating gate electrode layers 116 at an angle A1 (sidewall angle) ranging from approximately 90 degrees to approximately 93 degrees.

FIGS. 6 to 8 illustrate a first cycle of a trimming process 1000, a dry etching process 1050, and a wet etching process 1100, which is used to adjust the profile of the floating gate electrode layers 116 and a recess depth of the isolation structure 110. Referring to FIG. 6, a trimming process 1000 is performed on the floating gate electrode layers 116. The trimming process 1000 includes depositing a first silicon oxide layer 120. The first silicon oxide layer 120 extends over the upper surfaces and exposed sidewalls of the floating gate electrode layers 116, as well as the upper surface of the isolation structure 110. In one embodiment, the deposition process is an atomic layer deposition process. The atomic layer deposition process can be a thermal atomic layer deposition process or a plasma-enhanced atomic layer deposition process.

Atomic layer deposition may include multiple stages, such as a heating stage, a deposition stage, a cooling stage, and/or other suitable stages. In an embodiment using a thermal atomic layer deposition process, the deposition stage of the atomic layer deposition may include a plurality of cycles, such as 10 to 300 times. Each cycle sequentially includes (1) introducing a silicon-containing precursor into a deposition chamber, wherein the silicon-containing precursor is adsorbed on the active vacancies on the surface of the wafer; (2) vacuuming and purging the silicon-containing precursor; (3) introducing an oxygen-containing precursor into the deposition chamber, wherein the oxygen-containing precursor reacts with the silicon precursor adsorbed on the vacancies to form a single layer of the first silicon oxide layer 120; and (4) vacuuming and purging the oxygen-containing precursor and reaction byproducts. The cycle of the deposition stage may continue until the first silicon oxide layer 120 reaches the desired thickness.

The silicon-containing precursor may be hexachlorodisilane (Si₂Cl₆), bis(diethylamino)silane (BDEAS), and/or combinations thereof. The oxygen-containing precursor may be a mixture of oxygen radicals, hydrogen radicals, and hydroxyl radicals, which can be formed through homolysis by flowing a mixture of oxygen (O₂) and hydrogen (H₂) into the deposition chamber. In some embodiments, the ratio of the hydrogen flow rate to the oxygen flow rate ranges from approximately 0.1 to approximately 0.3. Hydrogen can facilitate the homolysis of oxygen, increasing the concentration of oxygen radicals.

In embodiments using a thermal atomic layer deposition process, the atomic layer deposition can be a high-temperature process in a furnace tube equipment that processes multiple batches of wafer simultaneously, also known as a batch isotropic oxidation process. In some embodiments, the atomic layer deposition process may be performed at a temperature of approximately 500° C. to approximately 800° C., or as a single-wafer, low-temperature process of approximately 50° C. to approximately 100° C. In embodiments using a plasma-enhanced atomic layer deposition process, the oxygen-containing precursor may be an oxygen plasma.

During the step of introducing oxygen-containing precursor in each cycle, oxygen radicals may diffuse through one or more monolayers of the first silicon oxide layer 120 and reach the surface of the floating gate electrode layers 116. The semiconductor material (e.g., silicon) of the floating gate electrode layers 116 is oxidized and consumed by the oxygen radicals. Thus, during the atomic layer deposition process of the first silicon oxide layer 120, the profile of the floating gate electrode layers 116 is trimmed, and a second silicon oxide layer 122 is formed (indicated on only one floating gate electrode layers 116 for illustrative purposes). Because the amount of oxidation is inversely related to the diffusion distance, the amount of consumption of the floating gate electrode layers 116 may gradually decrease from the top to the bottom. In other words, the width of the portions of the second silicon oxide layer 122 on the sides of the floating gate electrode layers 116 gradually decrease from the top to the bottom. The second silicon oxide layer 122 may have material properties, such as lattice structure and crystallinity, which is different from the first silicon oxide layer 120. The second silicon oxide layer 122 is also formed on the top surface of the floating gate electrode layers 116.

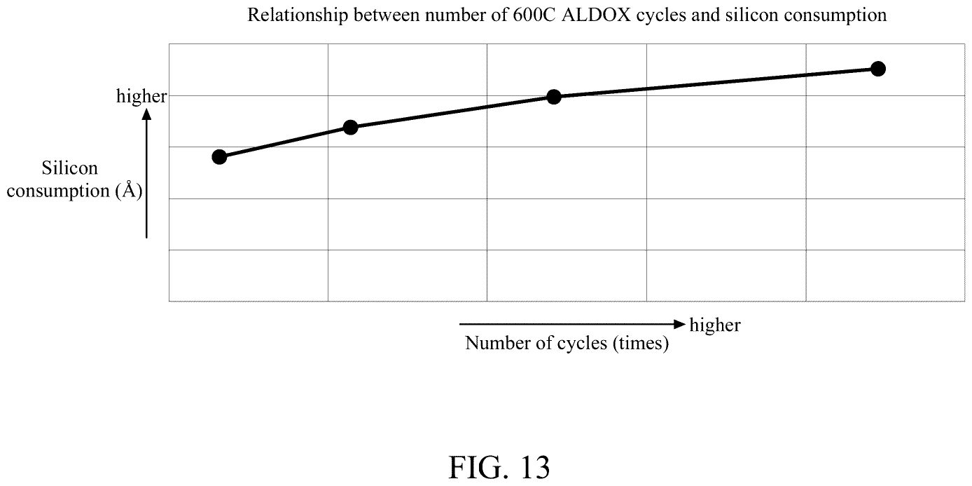

FIG. 13 shows a graph illustrating the relationship between the number of atomic layer deposition cycles and silicon consumption. In one embodiment, the trimming process 1000 uses a thermal atomic layer deposition process at 600° C. As the number of deposition cycles increases, the silicon consumption of the floating gate electrode layers 116 increases. In some embodiments, the silicon consumption rate is not constant. For example, the silicon consumption rate may decrease with increasing cycles. For example, the silicon consumption rate may be higher in the early stages of a cycle than that in the later stages of a cycle. In some other embodiments, the silicon consumption rate may be constant.

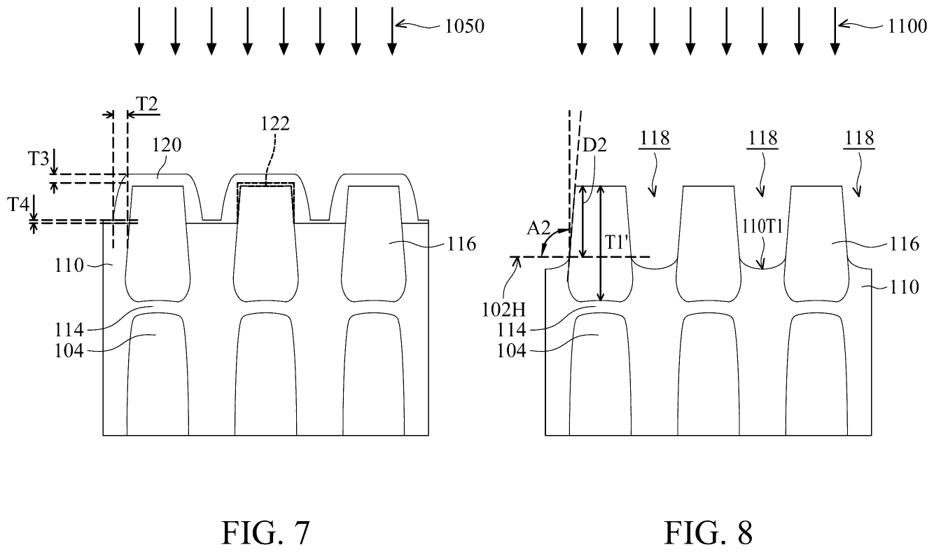

Referring to FIG. 7, a dry etching process 1050 is performed on the first silicon oxide layer 120 to thin the thickness of the first silicon oxide layer 120. The dry etching process 1050 may use a fluorocarbon plasma as an etchant. After the dry etching process 1050, the first silicon oxide layer 120 has a thickness T2 along the sidewalls of the floating gate electrode layers 116, a thickness T3 along the upper surfaces of the floating gate electrode layers 116, and a thickness T4 along the upper surface of the isolation structure 110. The thickness T2 is greater than the thickness T3 and greater than the thickness T4. In some embodiments, the first silicon oxide layer 120 along the upper surfaces of the floating gate electrode layers 116 is not completely removed (the thickness T3 is greater than zero). This prevents plasma damage to the gate electrode layer 116 from the dry etching process 1050, thereby increasing the yield and reliability of the semiconductor memory device. In some embodiments, the dry etching process 1050 may remove a portion of the first silicon oxide layer 120 along the upper surface of the isolation structure 110 (i.e., the thickness T4 is equal to zero) to expose the upper surface of the isolation structure 110.

Referring to FIG. 8, a wet etching process 1100 is performed. A buffered hydrofluoric acid solution (BHF) may be used for the wet etching process 1100. The wet etching process 1100 removes the first silicon oxide layer 120 and the second silicon oxide layer 122 and recesses the isolation structure 110 to vertically expand the trench 118. The ratio (D2/T1′) of the depth D2 of the trench 118 to the thickness T1′ of the floating gate electrode layers 116 ranges from approximately 1/5 to approximately 4/5. Ratio (D2/T1′) is greater than ratio (D1/T1). Thickness T1′ is less than thickness T1 due to oxidation of the upper portion of the floating gate electrode layers 116.

The trimming process 1000 causes the top of the trench 118 to have a larger opening width, which can improve the process difficulty of subsequently depositing the control gate electrode layer, for example, by preventing voids or seams formation within the control gate electrode layer, thereby improving the yield and reliability of the semiconductor memory device.

In some embodiments, because the thickness T2 of the first silicon oxide layer 120 along the sidewalls of the floating gate electrode layers 116 is greater than the thickness T4 of the first silicon oxide layer 120 along the upper surface of the isolation structure 110, the depth D2 can be controlled to a deeper position. Furthermore, this facilitates the formation of a V-shaped profile on the recessed upper surface 110T1 of the isolation structure 110, which is beneficial for reducing reduce parasitic capacitance between the floating gate electrode layers 116, thereby increasing the program/erase efficiency of the flash memory device.

After the wet etching process 1100, the sidewalls of the floating gate electrode layers 116 intersect the plane 102H parallel to the main surface of the semiconductor substrate 102 on the side outside the floating gate electrode layers 116 at an angle A2 (sidewall angle) ranging from approximately 91 degrees to approximately 98 degrees. The angle A2 is greater than the angle A1.

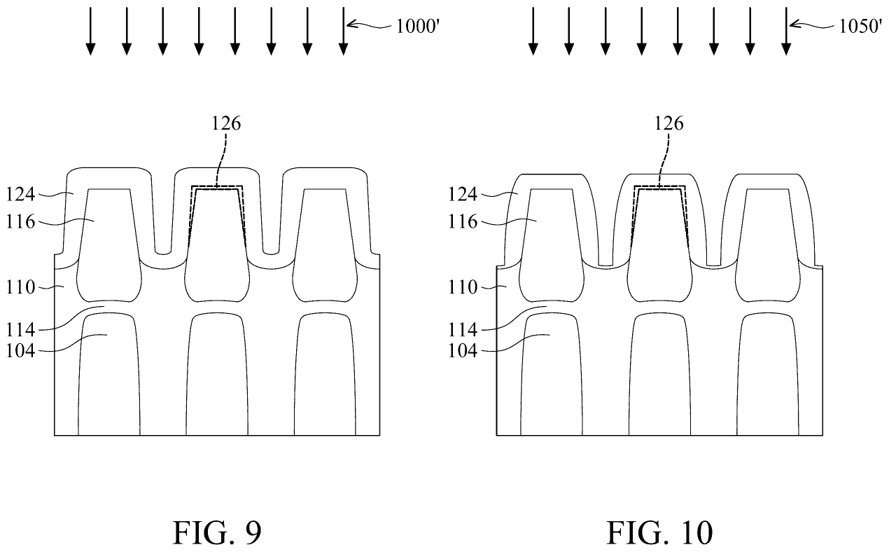

FIGS. 9 to 11 illustrate a second cycle of a trimming process 1000, a dry etching process 1050, and a wet etching process 1100 to further adjust the profile of the floating gate electrode layers 116 and the recess depth of the isolation structure 110. Referring to FIG. 9, a trimming process 1000′ is performed on the gate electrode layer 116. The trimming process 1000′ includes depositing a third silicon oxide layer 124. The third silicon oxide layer 124 extends over the upper surfaces and exposed sidewalls of the floating gate electrode layers 116, as well as the upper surface of the isolation structure 110. In one embodiment, the deposition process is an atomic layer deposition process. During the atomic layer deposition process of the third silicon oxide layer 124, the floating gate electrode layer 116 is oxidized to form a fourth silicon oxide layer 126, thereby trimming the profile of the floating gate electrode layer 116. The trimming process 1000′ may be similar to the trimming process 1000 and may use process parameters different from those of trimming process 1000 (e.g., number of cycles, temperature, etc.).

Referring to FIG. 10, a dry etching process 1050′ is performed on the third silicon oxide layer 124 to reduce the thickness of the third silicon oxide layer 124. In some embodiments, the third silicon oxide layer 124 along the upper surface of the isolation structure 110 may be removed to expose the upper surface of the isolation structure 110. The dry etching process 1050′ may be similar to the dry etching process 1050 and may use different process parameters (e.g., process time, plasma power, etc.) from the dry etching process 1050.

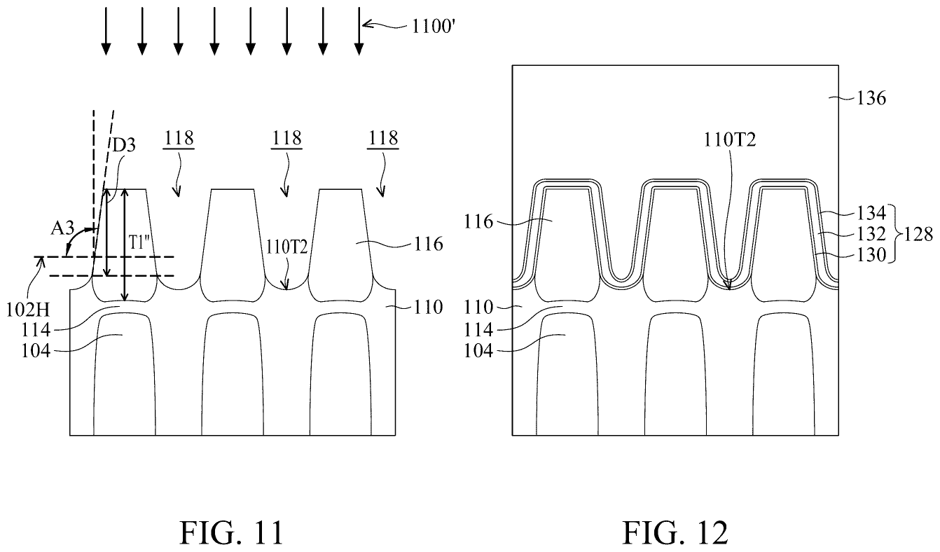

Referring to FIG. 11, an etching process (e.g., wet etching) 1100′ is performed on the third silicon oxide layer 124 and the fourth silicon oxide layer 126. The wet etching process 1100′ completely removes the third silicon oxide layer 124 and the fourth silicon oxide layer 126 and recesses the isolation structure 110 to further vertically expand the trenches 118. The wet etching process 1100′ may be similar to the wet etching process 1100 and may use different process parameters (e.g., process time) from the wet etching process 1100.

The ratio (D3/T1″) of the depth D3 of the trenches 118 to the thickness T1″ of the floating gate electrode layers 116 ranges from approximately 3/10 to approximately 9/10. The ratio (D3/T1″) is greater than the ratio (D2/T1′). The thickness T1″ may be smaller than the thickness T1′ due to oxidation of the upper portion of the floating gate electrode layers 116. After the wet etching process 1100′, the sidewalls of the floating gate electrode layers 116 intersect a plane 102H parallel to the main surface of the semiconductor substrate 102 on the side outside the floating gate electrode layers 116 at an angle A3 (sidewall angle) ranging from approximately 92 degrees to approximately 99 degrees. The angle A3 is greater than the angle A2. Furthermore, a recessed upper surface 110T2 of the isolation structure 110 may have a smaller radius of curvature than the upper surface 110T1.

Although the method embodiment uses two cycles of the trimming process 1000, dry etching process 1050, and wet etching process 1100, embodiments of the present disclosure are not limited thereto. The cycle may be performed only once or a plurality of times (e.g., 3-4 times) depending on the desired profile of the floating gate electrode layers 116 and/or the desired depth of the isolation structure 110. For example, excessive consumption of the floating gate electrode layers 116 may reduce the gate coupling ratio between the control gate electrode layer and the floating gate electrode layers; while insufficient consumption of the floating gate electrode layers 116 may increase the risk of voids or seams formation within the control gate electrode layer. The trenches 118 that are too shallow increase parasitic capacitance between the floating gate electrode layers 116; while the trenches 118 that are too deep increase the risk of unintended channel opening in the control gate electrode layer.

Referring to FIG. 12, an inter-gate dielectric structure 128 is formed along the upper surfaces and sidewalls of the floating gate electrode layers 116 and the upper surface 110T2 of the isolation structure 110 to partially fill the trenches 118. Next, a control gate electrode layer 136 is formed over the inter-gate dielectric structure 128 to overfill the trenches 118, thereby completing the fabrication of a flash memory device, such as a NOR-type flash memory device.

The inter-gate dielectric structure 128 may be a three-layer structure including an oxide layer 130/a nitride layer 132/an oxide layer 134. The control gate electrode layer 136 is formed of a conductive material, such as polysilicon, amorphous silicon, or a combination thereof and/or other conductive materials. The inter-gate dielectric structure 128 and the control gate electrode layer 136 may be deposited to form by using chemical vapor deposition (CVD).

According to the above description, embodiments of the present disclosure provide a flash memory device and a method for forming the same. Embodiments of the present disclosure use one or more cycles of a trimming process, a dry etching process, and a wet etching process to precisely control the floating gate electrode layer to have a desired profile, while concurrently controlling the recessing of the isolation structure to a desired depth. Therefore, the risk of defects formation within the floating gate electrode layers and/or the control gate electrode layer is reduced, which increases the yield and reliability of the semiconductor memory device and further increases its performance.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A method for forming a flash memory, comprising:
forming an isolation structure around a plurality of active regions;
forming a plurality of first gate electrode layers respectively on the active regions;
depositing a first silicon oxide layer along upper surfaces and sidewalls of the first gate electrode layers and an upper surface of the isolation structure;
performing a first dry etching process to thin the first silicon oxide layer;
performing a first wet etching process to remove the first silicon oxide layer and recess the isolation structure; and
forming a second gate electrode layer around the first gate electrode layers.

2. The method as claimed in claim 1, wherein the step of depositing the first silicon oxide layer comprises an atomic layer deposition process.

3. The method as claimed in claim 1, wherein the step of depositing the first silicon oxide layer comprises:
introducing a silicon-containing precursor; and
introducing an oxygen-containing precursor, wherein the silicon-containing precursor reacts with the oxygen-containing precursor to form the first silicon oxide layer.

4. The method as claimed in claim 3, wherein the oxygen-containing precursor diffuses through the first silicon oxide layer and oxidizes the first gate electrode layers to form a plurality of second silicon oxide layers respectively on the first gate electrode layers.

5. The method as claimed in claim 3, wherein the silicon-containing precursor is hexachlorodisilane, bis(diethylamino)silane, or a combination thereof, and the oxygen-containing precursor comprises a mixture of oxygen radicals, hydrogen radicals, and hydroxyl radicals.

6. The method as claimed in claim 1, wherein the isolation structure is recessed so that the isolation structure has a V-shaped upper surface.

7. The method as claimed in claim 1, wherein after performing the first dry etching process, the first silicon oxide layer remains covering the upper surfaces and the sidewalls of the first gate electrode layers.

8. The method as claimed in claim 1, wherein after performing the first dry etching process, the first silicon oxide layers have a first thickness at portions along the sidewalls of the first gate electrode layers, and the first silicon oxide layers have a second thickness at portions along the upper surface of the isolation structure, wherein the second thickness is less than the first thickness.

9. The method as claimed in claim 1, further comprising, before forming the second gate electrode layer around the first gate electrode layers:
depositing a second silicon oxide layer along the upper surfaces and the sidewalls of the first gate electrode layers and the upper surface of the isolation structure;
performing a second dry etching process to thin the second silicon oxide layer; and
performing a second wet etching process to remove the second silicon oxide layer and recess the isolation structure,
wherein the first wet etching process recesses the isolation structure to form a first trench, wherein a ratio of a depth of the first trench to a thickness of the first gate electrode layers is a first ratio, and the second wet etching process recesses the isolation structure to form a second trench, wherein a ratio of a depth of the second trench to the thickness of the first gate electrode layers is a second ratio, and the second ratio is greater than the first ratio.

10. The method as claimed in claim 9, wherein during the deposition of the second silicon oxide layer, the first gate electrode layers are oxidized to form a plurality of third silicon oxide layers respectively on the first gate electrode layers.

11. The method as claimed in claim 1, wherein the step of depositing the first silicon oxide layer is performed in a furnace tube equipment.

12. A method for forming a flash memory, comprising:
forming a strip pattern on a semiconductor substrate, wherein the strip pattern comprises active regions and a mask layer on the active regions;
forming an isolation structure around the strip pattern;
removing the mask layer of the strip pattern;
forming a floating gate electrode layer on the active regions;
trimming the floating gate electrode layer by performing a first trimming process, the first trimming process comprising oxidizing a first portion of the floating gate electrode layer to form a first silicon oxide layer;
performing a first wet etching process to remove the first silicon oxide layer and to recess the isolation structure; and
forming a control gate electrode layer on the isolation structure and the floating gate electrode layer.

13. The method as claimed in claim 12, wherein:
before the first trimming process, a sidewall of the floating gate electrode layer intersects a surface parallel to a surface of a semiconductor substrate at a first sidewall angle; and
after the first trimming process, the sidewall of the floating gate electrode layer intersects a surface parallel to the surface of the semiconductor substrate at a second sidewall angle, wherein the second sidewall angle is greater than the first sidewall angle.

14. The method as claimed in claim 12, wherein the first trimming process comprises performing a deposition process having a plurality of cycles to form a second silicon oxide layer, wherein during the deposition process, the first portion of the floating gate electrode layer is oxidized to form the first silicon oxide layer.

15. The method as claimed in claim 14, wherein each of the cycles of the deposition process comprises:
introducing a silicon-containing precursor; and
introducing a mixture of hydrogen and oxygen, wherein the oxygen undergoes homolysis to form oxygen radicals.

16. The method as claimed in claim 15, wherein:
the oxygen radicals diffuse through the second silicon oxide layer to the floating gate electrode layer to oxidize the first portion of the floating gate electrode layer;
in a first cycle of the cycles, the floating gate electrode layer is oxidized at a first rate;
in a second cycle of the cycles, the floating gate electrode layer is oxidized at a second rate;
the second cycle is performed after the first cycle; and
the second rate is lower than the first rate.

17. The method as claimed in claim 14, wherein performing the first wet etching process further removes the second silicon oxide layer.

18. The method as claimed in claim 14, further comprising: after the first trimming process and before the first wet etching process: performing a dry etching process to partially etch the second silicon oxide layer.

19. The method as claimed in claim 12, further comprising:
forming an inter-gate dielectric structure on the floating gate electrode layer, wherein the control gate electrode layer is formed on the inter-gate dielectric structure.

20. The method as claimed in claim 12, further comprising, after the first wet etching process and before forming the control gate electrode layer:
performing a second trimming process on the floating gate electrode layer, the second trimming process comprising performing a deposition process to form a second silicon oxide layer, wherein during the deposition process, a second portion of the floating gate electrode layer is oxidized to form a third silicon oxide layer;
performing a dry etching process to partially etch the second silicon oxide layer; and
performing a second wet etching process to remove the second silicon oxide layer and the third silicon oxide layer and to recess the isolation structure.
